(19) United States
(12) Patent Application Publication
(10) Pub. No.: US 2007/0298547 A1
(43) Pub. Date: Dec. 27, 2007

(54) Semiconductor device having a composite passivation layer and method of manufacturing the same

(75) Inventors: Po-Kang Hu, Tainan (TW); Ta-Wei Tung, Taichung (TW)

Correspondence Address: NIXON PEABODY LLP - PATENT GROUP, CLINTON SQUARE, P.O. BOX 31051, ROCHESTER, NY, 14603-1051, US

(73) Assignee: Promos Technologies Inc., Hsinchu (TW)

(21) Appl. No.: 11/510,937

(22) Filed: Aug. 28, 2006

(30) Foreign Application Priority Data
Jun. 22, 2006 (TW) 095122411

(51) Int. Cl. H01L 21/82; H01L 21/326; H01L 21/44

(52) U.S. Cl. 438/132; 438/467; 438/601

(57) ABSTRACT

A semiconductor device and a method of manufacturing the same are provided. The semiconductor device comprises a fuse bank with a fuse window, a pad area with a pad window, and a composite passivation layer comprising a sacrificial dielectric layer and a final passivation layer. Both the fuse window and the pad window have a bottom portion and two sidewalls, and the composite passivation layer covers both the fuse bank and the pad area except for the bottom portions of the fuse bank and the pad area.

This application claims priority to Taiwan Patent Application No. 095122411 filed on Jun. 22, 2006.

### CROSS-REFERENCES TO RELATED APPLICATIONS

Not applicable.

### BACKGROUND OF THE INVENTION

1. Field of the Invention

The subject invention relates to a semiconductor device comprising a composite passivation layer and a method of manufacturing the same; in particular, the invention relates to a semiconductor device comprising a polyimide-containing composite passivation layer and a method of manufacturing the same.

2. Descriptions of the Related Art

During the manufacturing of multi-level integrated circuits, the main frame of the integrated circuits is established after metallization and planarization. To protect the established, yet fragile integrated circuits from mechanical damage or contamination of moisture and/or particles, a passivation layer is typically deposited on the surface of the integrated circuits during the post manufacturing processes.

In a semiconductor device, the passivation layer normally covers two areas of the semiconductor device: the fuse bank and the pad area. To reach the highest manufacturing yield and product quality, several tests are performed at different manufacturing stages to detect any device defects as soon as possible. The arrangement of the fuse bank serves to adjust the connection of the circuits on the chip when any defects of any semiconductor device are detected. As a result, the failure of the whole chip due to defects of any semiconductor device thereon is prevented.

Generally, the fuse element is configured in the fuse bank of a semiconductor device to provide a redundant circuit. As a defect in a chip is detected, a laser repair is performed. Another circuit is then generated, by utilizing the laser energy, to cut a part of the inter-metal lines of the fuse structure to adjust the circuit connection on the chip. In other words, a redundant circuit generated from the fuse element is used to replace the defect portion, such that the chip with the defect(s) is still usable and the manufacturing yield is enhanced. On the other hand, the pad area is used to connect the internal integrated circuits of the semiconductor device to external circuits in the subsequent packing process.

Currently, a single-mask process is commonly used to form the fuse bank and the pad area of a semiconductor device. FIG. 1A to FIG. 1C illustrates such traditional single-mask processes that use one single mask. Referring to FIG. 1A, a fuse bank 2 and a pad area 4 are generated on a substrate of a semiconductor device, wherein the fuse bank 2 comprises a metal fuse element 10, a dielectric layer 20, and a metal line 30. The dielectric layer 20 is disposed above the metal fuse element 10, while the metal line 30 is disposed in the dielectric layer 20. In addition, the pad area 4 comprises a metal pad 40 in the dielectric layer 20. Referring to FIG. 1B again, a patterned final passivation layer 50 is formed in the fuse bank 2 and the pad area 4 on the dielectric layer 20 with the use of an appropriate mask (not shown). Afterwards, as illustrated in FIG. 1C, the patterned final passivation layer 50 is used as a mask for etching the dielectric layer 20 in the fuse bank 2 and the pad area 4 to form a fuse window A and a pad window B, respectively. The metal line 30 is disposed on the sidewall of the fuse window A while the metal pad 40 is disposed on the bottom portion of the pad window B.

The above-mentioned single-mask process succeeds in minimizing the number of masks needed, and thus, saves the cost. However, the sidewall of the fuse window A, formed by this process, is not sealed by any passivation layer and thus, is exposed to contamination by atmosphere moisture and particles. Moreover, since the process is limited by the patterning revolution of the final passivation layer 50, the space between the fuse window A and the metal line 30 is normally too thin. Therefore, the single-mask process cannot provide reliable protection and insulation for the metal line 30 in the dielectric layer 20.

Therefore, an improvement to the single-mask process is demanded in the industry. More specifically, a proper passivation layer for the fuse bank and the pad area to effectively protect the integrated circuits of the semiconductor device and to increase the yield of the manufacturing process is needed. The present invention is developed according to the above-mentioned demand and provides a solution to the problems to which semiconductor devices currently face.

### SUMMARY OF THE INVENTION

The primary objective of this invention is to provide a semiconductor device, which comprises a fuse bank with a fuse window, a pad area with a pad window, and a final passivation layer. The fuse window has a bottom portion and two sidewalls, the pad window has a bottom portion and two sidewalls, and the final passivation layer is a composite layer and covers the fuse bank and the pad area except for the bottom portion of the fuse window and the pad window. The final passivation composite layer not only protects the sidewall of the fuse window from contamination of atmosphere moisture and/or particles, but also adheres well to the sidewall of the fuse bank. As a result, the peeling problem that usually occurs between the final passivation layer and the sidewall of the fuse bank is eliminated, thereby, effectively enhancing the yield of semiconductor devices.

Another objective of this invention is to provide a method of manufacturing a semiconductor device. The method comprises the following steps: providing a substrate with a fuse bank and a pad area thereon; forming a fuse window in the fuse bank and a pad window in the pad area, respectively, wherein each the fuse window and the pad window has a bottom portion and two sidewalls; and forming a patterned final passivation layer to cover the fuse bank and the pad area, except for the bottom portion of the fuse window and the pad window.

Yet a further objective of this invention is to provide a composite passivation layer for use in a semiconductor device. The composite passivation layer comprises a sacrificial dielectric layer that is in direct contact with the semiconductor device. In addition the passivation layer comprises a polyimide layer that covers the sacrificial dielectric layer, wherein the sacrificial dielectric layer is a silicon nitride layer or a silicon oxy-nitride layer. The surface of the semiconductor device to be protected by the composite passivation layer comprises a silicon dioxide surface.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A to FIG. 1C illustrates the conventional single-mask process for forming a passivation layer in a semiconductor device;

FIG. 2A to FIG. 2D illustrates a first embodiment of the two-mask process of the present invention for forming a passivation layer in a semiconductor device; and

FIG. 3A to FIG. 3E illustrates a second embodiment of the two-mask process of the present invention for forming a passivation layer in a semiconductor device.

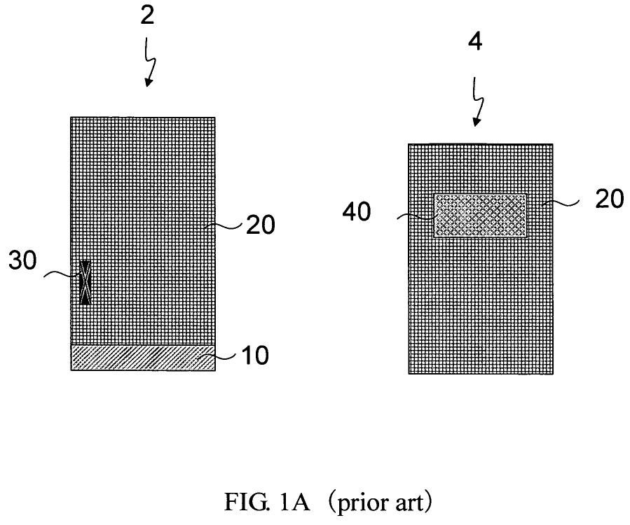

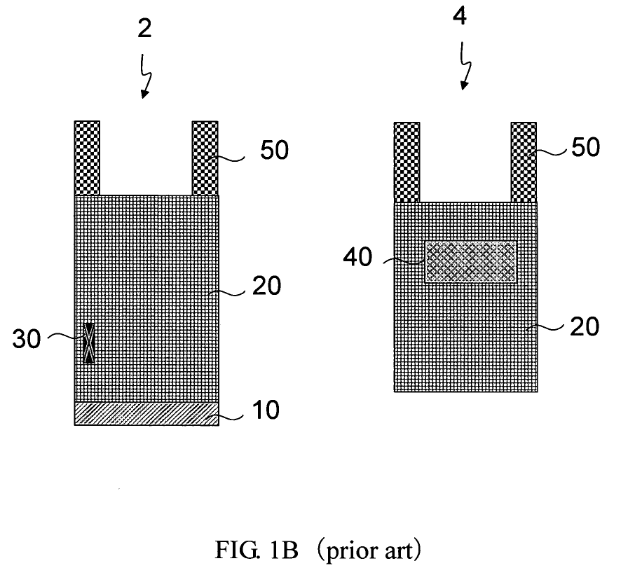

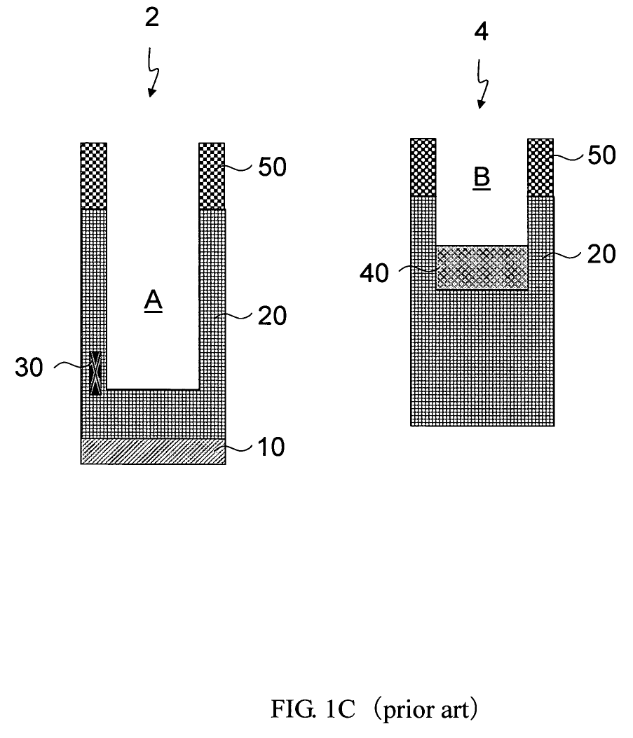

### DESCRIPTION OF THE PREFERRED EMBODIMENT

The following embodiments are provided to illustrate how the present invention solves the problems and disadvantages of the prior art. Specifically, the present invention adapts a two-mask process to solve the disadvantages of the conventional single-mask process.

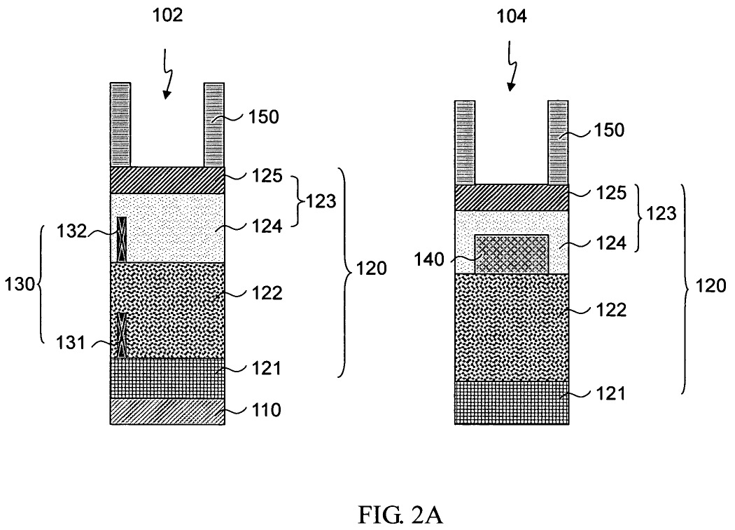

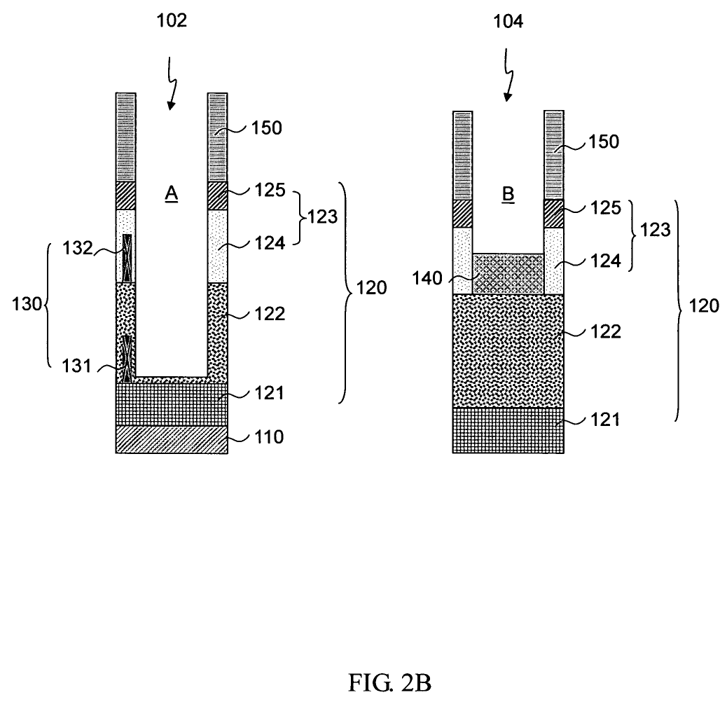

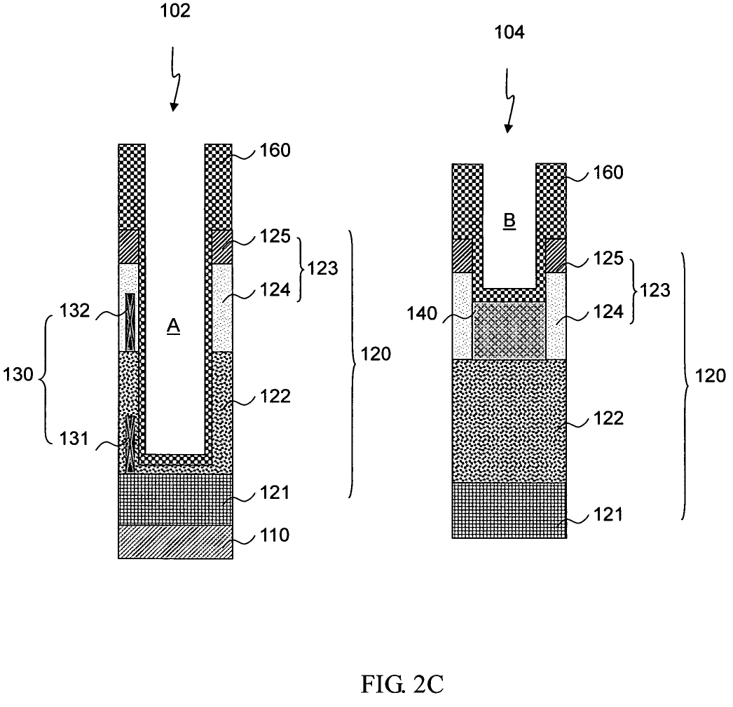

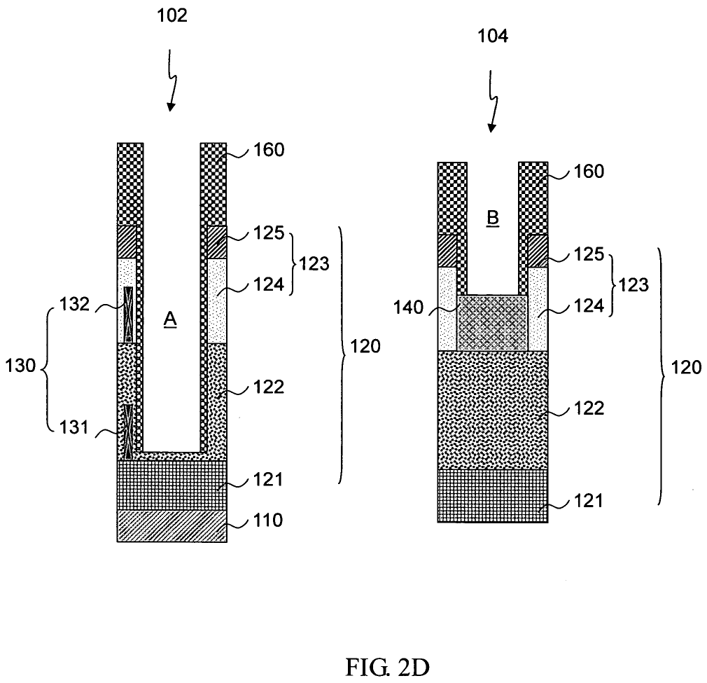

FIG. 2A to FIG. 2D illustrate the first embodiment of the manufacturing process of the present invention. First, as shown in FIG. 2A, a fuse bank 102 and a pad area 104 are provided on a silicon substrate (not shown), wherein the fuse bank 102 typically comprises a metal fuse element 110, a dielectric layer 120, and a metal line 130. The dielectric layer 120 is disposed above the metal pad element 110, while the metal line 130 is disposed in the dielectric layer 120. On the other hand, the dielectric layer 120 in the pad area 104 comprises a metal pad 140 therein.

Referring to FIG. 2A again, a first mask (not shown) is used to form a patterned photoresist 150 on the dielectric layer 120 of the fuse bank 102 and the pad area 104. Afterwards, as shown in FIG. 2B, a process, such as an anisotropic etching process, is performed to remove a portion from both the dielectric layer 120 of the fuse bank 102 and the pad area 104 with the use of the patterned photoresist 150, to form a fuse window A and a pad window B, each of which has a hollow structure with a bottom portion and two sidewalls. The bottom portion of the fuse window A is disposed in the dielectric layer 120, while the bottom portion of the fuse window B is disposed on the upper surface of the metal pad 140 in the dielectric layer 120.

Next, referring to FIG. 2C, a final passivation layer 160 is deposited to cover the fuse window A and the pad window B after the removal of the patterned photoresist 150. Afterwards, as shown in FIG. 2D, the final passivation layer 160 is patterned by using a second mask (not shown) to expose both the dielectric layer 120 in the bottom portion of the fuse window A and the metal pad 140 in the bottom portion of the pad window B. That is, in the two-mask process, the final passivation layer 160 covers not only the top surface of the dielectric layer 120 of the fuse bank 102 and the pad area 104, but also the sidewalls of the fuse window A and the pad window B. Still, the bottom portions of the fuse window A and the pad window B are exposed.

During the application of the manufacturing process, illustrated by FIG. 2A to FIG. 2D, the dielectric layer 120 of the fuse bank 102 and the pad area 104 typically comprises bottom up an inter-layer dielectric layer 121, an inter-metal dielectric layer 122, and a passivation layer 123, wherein the passivation layer 123 is typically a composite layer. For example, the passivation layer 123 may comprise bottom up a first passivation layer 124 and a second passivation layer 125. In this embodiment, the bottom portion of the fuse window A in the fuse bank 102 is disposed in the inter-metal dielectric layer 122, while the metal pad 140 of the pad area 104 is disposed in the first passivation layer 124. Moreover, the fuse bank 102 may comprise two kinds of metal lines: an inter-metal line 131 in the inter-metal dielectric layer 122 and a top metal line 132 in the first passivation layer 124.

In the embodiment where the dielectric layer 120 comprises an inter-layer dielectric layer 121, an inter-metal dielectric layer 122, and a passivation layer 123, the inter-metal dielectric layer 122 may be a silicon dioxide layer, or a silicon dioxide layer with a low dielectric constant (low-k layer). The use of a low-k layer effectively decreases the capacitance thereof so as to eliminate the influence of RC delay in the semiconductor device. Moreover, the first passivation layer 124 in the passaivation layer 123 may be a silicon oxide layer, while the second passivation layer 125 may be a silicon nitride layer. Optionally, the second passivation layer 125 may be a composite layer (not shown) that comprises a silicon oxy-nitride layer and a silicon nitride layer, wherein the silicon oxy-nitride layer is disposed under the silicon nitride layer to serve as a buffer layer between the first passivation layer 124 and the silicon nitride layer to address the peeling problem that occurs between the first passivation layer 124 and the second passivation (composite) layer 125.

The final passivation layer 160 used to seal the sidewall of the fuse window A is preferably a polyimide layer. Polyimide is suitable for use in a passivation layer for protecting integrated circuits because of its good optical and insulating properties, as well as its chemical resistance and mechanical properties. By sealing the sidewall of the fuse window A with the final passivation layer 160, atmosphere moisture or particle contamination on the thin sidewall of the fuse window in the conventional single-mask process can be prevented. However, several problems still exist in real applications. As shown in FIG. 2C, when depositing the final passivation layer 160, layer 160 will directly come into contact with the metal pad 140 in the bottom portion of pad window B. By using polyimide for the final passivation layer 160, the metal pad 140 will erode accordingly. Furthermore, in the photolithography process conducted after the deposition of final passivation layer 160, if a rework is required because of any defect in the process, the metal pad 140 is exposed to the rework condition. If polyimide is used to provide the final passivation layer 160, the rework condition will erode or completely remove the metal pad 140.

It has also been noted that the adhesion between the polyimide final passivation layer 160 and the silicon dioxide dielectric layer 120 is weak. A weak adhesion is exacerbated when a low-k layer is adapted as layer 120. Therefore, if polyimide is used to provide the final passivation layer 160 and a low-k silicon dioxide is used to provide any layer of the dielectric layer 120, a peeling phenomenon will occur because of the poor adhesion between the final passivation layer 160 and the silicon dioxide layer (such as between the final passivation layer 160 and the inter-metal dielectric layer 122, and/or between the final passivation layer 160 and first passivation layer 124). Therefore, the final passivation layer 160 could easily peel off the sidewall of the fuse window A, and the pad window B would be over-open.

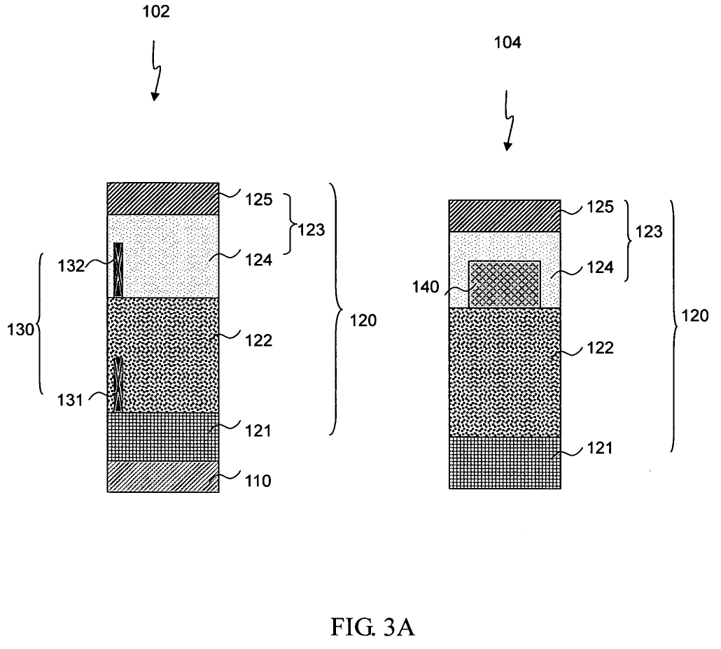

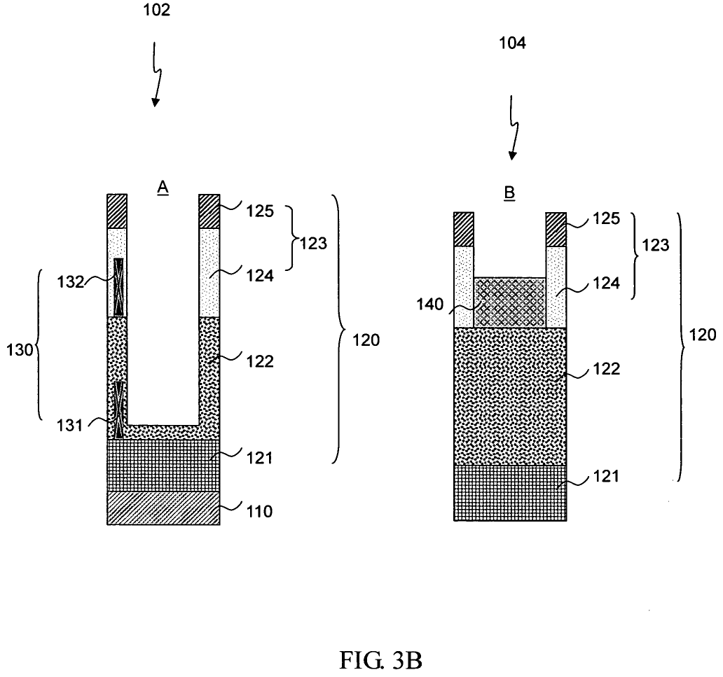

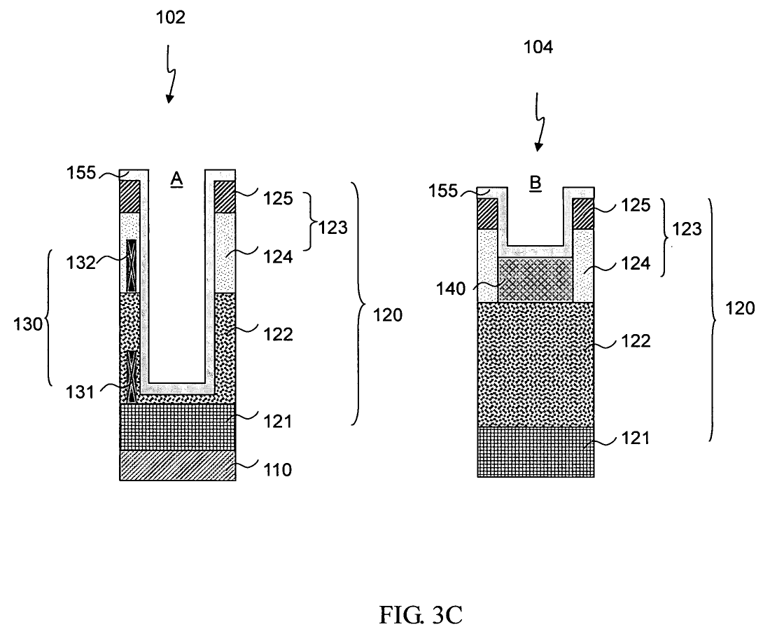

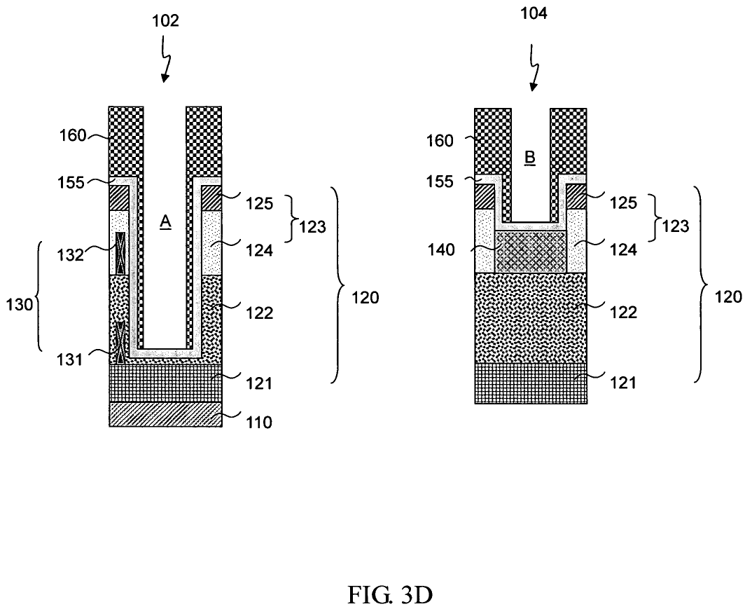

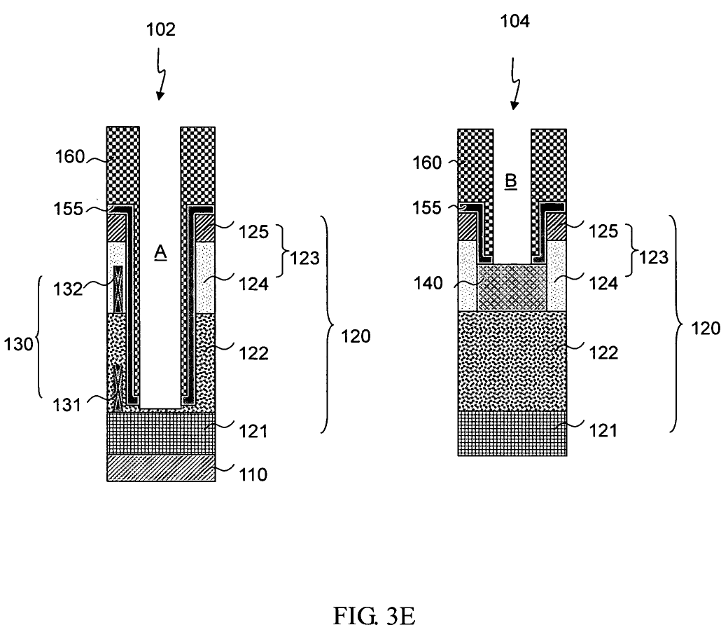

The present invention further provides another solution to avoid the above-mentioned peeling and/or over-open. Please refer to FIG. 3A to FIG. 3E, wherein the structure of the semiconductor device shown in FIG. 3A is essentially the same as that in FIG. 2A. A detailed description in this respect is omitted.

Referring to FIG. 3B, after the formation of a photoresist (not shown) on the dielectric layer 120 of the fuse bank 102 and the pad area 104 of the afore-mentioned semiconductor device, the photoresist is patterned into a first patterned photoresist (not shown) by using a first mask (not shown). The first patterned photoresist is used as a mask for etching and removing a portion from the dielectric layer 120 of the fuse bank 102 and the pad area 104 to form a fuse window A and a pad window B, respectively. Both the fuse window A and the pad window B have a hollow structure with a bottom portion and two sidewalls. Specifically, in the embodiment wherein the dielectric layer 120 comprises an inter-layer dielectric layer 121, an inter-metal dielectric layer 122, and a passivation composite layer 123, comprising a first passivation layer 124 and a second passivation layer 125, a portion is removed from the inter-metal dielectric layer 122, the first passivation layer 124, and the second passivation layer 125 in the fuse bank 102 and a portion is removed from each of the first passivation layer 124, and the second passivation layer 125 in the pad area 104, to form fuse window A and pad window B, respectively. The bottom portion of the fuse window A is disposed in the inter-metal dielectric layer 122, while the bottom portion of the pad window B is disposed in the first passivation layer 124. Alternatively, a portion is removed from the inter-layer dielectric layer 121 in the fuse bank 102 along with the forming of fuse window A, so that the bottom portion of the fuse window A is disposed in the inter-layer dielectric layer 121. Moreover, the two kinds of metal lines in the sidewall of the fuse window A, i.e., the inter-metal line 131 and the top metal line 132, are disposed in the inter-metal dielectric layer 122 and the first passivation layer 124, respectively. Thereafter, the patterned photoresist is removed.

Referring to FIG. 3C, a sacrificial dielectric layer 155 is formed conformally to cover the top surface of the second passivation layer 125 of the fuse bank 102 and the sidewalls and bottom portion of the fuse window A thereof. The dialectic layer also covers the top surface of the second passivation layer 125 of the pad area 104 and the sidewalls and bottom portion of the pad window B thereof. Preferably, the sacrificial dielectric layer 155 is a silicon nitride layer or a silicon oxy-nitride layer with a thickness less than half the width of the fuse window A and the pad window B. For instance, the thickness of the silicon nitride layer may range from about 2 to 3 μm when the width of the fuse window A ranges from about 6 to 7 μm.

Next referring to FIG. 3D, a final passivation layer 160 is formed to cover the sacrificial dielectric layer 155. Preferably, the final passivation layer 160 is a polyimide layer. Afterwards, a second patterned photoresist (not shown) is formed. The final passivation layer 160 is patterned accordingly to etch away a portion from both the layer 160 above the bottom portion of the fuse window A and that above the bottom portion of the pad window B, to expose both a portion of the sacrificial dielectric layer 155 above the bottom portion of the fuse window A and that above the bottom portion of the pad window B.

Lastly, referring to FIG. 3E, the patterned final passivation layer 160 is used as a mask to etch away a portion from both the sacrificial dielectric layer 155 above the bottom portion of the fuse window A and that above the bottom portion of the pad window B, to expose both the inter-metal dielectric layer 122 (or the inter-dielectric layer 121) at the bottom portion of the fuse window A and the metal pad 140 at the bottom portion of the pad window B.

The above approach is substantially similar to the two-mask process illustrated by FIGS. 2A to 2E with regards to material selections and variations for each layer except that the final passivation layer is a composite layer. Therefore, the details regarding material selections and variations will not be further described herein.

Accordingly, the second embodiment of the present invention relates to a semiconductor device with a composite passivation layer. The semiconductor device comprises a fuse bank 102 with a fuse window A, a pad area with a pad window B, and a composite passivation layer comprising a sacrificial dielectric layer 155 and a final passivation layer 160. Both the fuse window A and pad window B comprise a bottom portion and two sidewalls. The composite passivation layer covers both the fuse bank 102 and the pad area 104, except for the bottom portion of the fuse window A and the pad window B. Compared with the semiconductor device provided by the conventional single-mask process, the present invention primarily differs from the conventional process in two ways: the final passivation layer is replaced by a composite layer and the two areas, i.e., fuse bank and pad area, are covered by the composite layer except for the bottom portion of the fuse window A and the pad window B.

Specifically, the present invention provides a semiconductor device wherein both the fuse bank 102 and the pad area 104 comprise a dielectric layer 120. In a real application such as that illustrated in FIG. 3E, the dielectric layer 120 comprises bottom up an inter-layer dielectric layer 121, an inter-metal dielectric layer 122, and a passivation layer 123, wherein the passivation layer 123 is typically a composite layer which comprises a first passivation layer 124 and a second passivation layer 125. Moreover, the fuse bank 102 comprises a metal fuse element 110 disposed under the inter-dielectric layer 121 with two types of metal lines disposed in the sidewall of the fuse window A: an inter-metal line 131 in the inter-metal dielectric layer 122, and a top metal line 132 in the first passivation layer 124. The pad area 104 comprises a metal pad 140 disposed in the first passivation layer 124 above the inter-metal dielectric layer 122.

In the above-mentioned real application, a sacrificial dielectric layer 155 is provided to cover the top surface of the second passivation layer 125 and the fuse window A in the fuse bank 102, wherein the fuse window A is covered by layer 155 both at its sidewalls and at the parts of its bottom portion that are against the sidewalls, to contact the inter-metal dielectric layer 122, first passivation layer 124, and second passivation layer 125 (or the inter-dielectric layer 121, the inter-metal dielectric layer 122, the first passivation layer 124, and the second passivation layer 125) in the fuse bank 102. The sacrificial dielectric layer 155 also covers the top surface of the second passivation layer 125 and the pad window B in the pad area 104, wherein the pad window B is covered by layer 155 both at its sidewalls and at the part of its bottom portion that are against the sidewalls, to contact the first passivation layer 124 and the second passivation layer 125 in the pad window B as well as the parts of the metal pad 140 against the sidewalls of window B. Specifically, the final passivation layer 160 does not come into direct contact with the top surface of the second passivation layer 125, the fuse window A, or the pad window B. Preferably, the sacrificial dielectric layer 155 is a silicon nitride layer or a silicon oxy-nitride layer and the final passivation layer 160 is a polyimide layer.

Compared with the prior art, the semiconductor device of the present invention, manufactured by the two-mask process disclosed herein, has a passivation layer on the sidewalls of the fuse window to provide protection and insulation efficacy. The passivation layer effectively protects the metal line(s) inside the sidewall of the fuse window from contamination of atmosphere moisture and/or particles. Moreover, in a preferred embodiment of the present invention wherein a composite layer, comprising a silicon nitride layer (or silicon oxy-nitride layer) as the sacrificial dielectric layer and a polyimide layer as the final passivation layer, is used as the final protection layer, the sacrificial dielectric layer adheres well both to the dielectric layers of the sidewalls of the fuse window and the pad window and to the final passivation layer. Therefore, the over-open and/or peeling problems occurred in the conventional single-mask process are eliminated, substantially enhancing the manufacturing yield.

Moreover, in the embodiment of the present invention wherein a composite passivation layer is adopted, the undesired direct contact of the metal pad in the pad window with polyimide during the deposition of the polyimide final passivation layer is effectively avoided because of the presence of a silicon nitride layer (or a silicon oxy-nitride layer) above the metal pad as a sacrificial dielectric layer. Accordingly, the problem of the metal pad eroding due to polyimide can be effectively avoided. Furthermore, since a sacrificial dielectric layer is disposed between the metal pad and the polyimide final passivation layer, the metal pad will not erode because of the alkaline environment required for reworking the polyimide layer due to the misalignment that occurs in the photolithography process of the polyimide layer. The process window of reworking the polyimide layer can be increased accordingly.

Given the above, the present invention provides a semiconductor device with a passivation composite layer and a method of fabricating the same. The present invention effectively solves the problems of the conventional one-mask process, enhancing device reliability and manufacturing yield.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A method of manufacturing a semiconductor device, comprising:
providing a substrate with a fuse bank and a pad area thereon;
forming a fuse window in the fuse bank and a pad window in the pad area, wherein each the fuse window and the pad window has a bottom portion and two sidewalls;
forming a sacrificial dielectric layer to cover the sidewalls of the fuse window and the pad windows; and
forming a final passivation layer on the sacrificial dielectric layer to cover both the fuse bank and the pad area except for the bottom portions of the fuse window and the pad window.

2. The method of claim 1, wherein each of the fuse bank and the pad area comprises top down a passivation layer, an inter-metal dielectric layer, and an inter-layer dielectric layer, wherein the bottom portion of the fuse window is disposed in the inter-metal dielectric layer and the bottom portion of the pad window is disposed in the passivation layer.

3. The method of claim 1, wherein the sacrificial dielectric layer is a silicon nitride layer or a silicon oxy-nitride layer.

4. The method of claim 1, wherein the final passivation layer is a polyimide layer.

5. The method of claim 1, wherein the steps of forming the sacrificial dielectric layer and forming the final passivation layer comprise:
forming the sacrificial dielectric layer on the substrate to cover the fuse bank and the pad area conformally such that both the sidewalls and bottom portion of the fuse window and those of the pad window are covered by the sacrificial dielectric layer;
forming the final passivation layer to cover the sacrificial dielectric layer;
forming a patterned photoresist layer on the final passivation layer;
removing a portion from both the final passivation layer above the bottom portion of the fuse window and that above the bottom portion of the pad window by using the patterned photoresist layer as a first mask, while remaining a portion of the final passivation layer on the sidewalls of each of the fuse window and the pad window; and
removing a portion from both the sacrificial dielectric layer above the bottom portion of the fuse window and that above the bottom portion of the pad window by using the patterned final passivation layer as a second mask, to expose the bottom portions of the fuse window and the pad window.

6. The method of claim 5, wherein each of the fuse bank and the pad area comprises two down a passivation layer, an inter-metal dielectric layer, and an inter-layer dielectric layer, wherein the bottom portion of the fuse window is disposed in the inter-metal dielectric layer and that of the pad window is disposed in the passivation layer, and wherein the step of using the patterned final passivation layer as the second mask also removes the inter-metal dielectric layer at the bottom portion of the fuse window to expose the inter-layer dielectric layer in the fuse bank.

7. The method of claim 6, wherein each of the passivation layers of the fuse bank and the pad area comprises top down a first passivation layer and a second passivation layer, and the bottom portion of the pad window is disposed in the first passivation layer.

8. A semiconductor device, comprising:
a fuse bank with a fuse window, wherein the fuse window has a bottom portion and two sidewalls;
a pad area with a pad window, wherein the pad window has a bottom portion and two sidewalls;
a sacrificial dielectric layer, conformally covering the sidewalls of the fuse window and the pad window and exposing the bottom portions of the fuse window and the pad window; and
a final passivation layer, covering the sacrificial dielectric layer in the fuse bank and the pad area but exposing the bottom portions of the fuse window and the pad window therein.

9. The semiconductor device of claim 8, wherein the sacrificial dielectric layer is a silicon nitride layer or a silicon oxy-nitride layer.

10. The semiconductor device of claim 8, wherein the final passivation layer is a polyimide layer.

11. The semiconductor device of claim 8, wherein each of the fuse bank and the pad area comprises top down a passivation layer, an inter-metal dielectric layer, and an inter-layer dielectric layer, wherein the bottom portion of the pad window is disposed in the passivation layer.

12. The semiconductor device of claim 11, wherein the bottom portion of the fuse window is disposed in the inter-metal dielectric layer.

13. The semiconductor device of claim 11, wherein the bottom portion of the fuse window is disposed in the inter-layer dielectric layer.

14. The semiconductor device of claim 11, wherein the passivation layer of each of the fuse bank and the pad area comprises top down a first passivation layer and a second passivation layer, wherein the bottom portion of the pad window is disposed in the first passivation layer.

15. A composite passivation layer for a semiconductor device, comprising:
a sacrificial dielectric layer, conformally and directly contacting the semiconductor device; and
a polyimide layer, covering the sacrificial dielectric layer,
wherein the sacrificial dielectric layer is a silicon nitride layer or a silicon oxy-nitride layer and the surface of the semiconductor device to be covered and protected by the composite passivation layer comprises a silicon dioxide surface.

16. The composite passivation layer of claim 15, wherein the silicon dioxide surface is typically made of a silicon dioxide having a low dielectric constant.

17. A method of manufacturing a semiconductor device, comprising:
providing a substrate with a fuse bank having a fuse element and a pad area having a pad thereon;
forming a fuse window above the fuse element and in a dielectric layer in the fuse bank, wherein the fuse window has a bottom portion and a sidewall;
forming a pad window in the pad area, wherein the pad window has a bottom portion and a sidewall and the bottom portion is an upper surface of the pad;
forming a sacrificial dielectric layer to cover both the bottom portion and sidewall of the fuse window and those of the pad window conformally;
forming a patterned final passivation layer to cover the sacrificial dielectric layer while exposing the bottom portions of the fuse window and the pad window; and
removing a portion both from the sacrificial dielectric layer above the bottom portion of the fuse window and from the sacrificial dielectric layer above the bottom portion of the pad window by using the patterned final passivation as a mask, to expose an upper surface of the dielectric layer in the fuse bank and the upper surface of the pad in the pad area.

18. The method of claim 17, wherein the sacrificial dielectric layer is a silicon nitride layer or a silicon oxy-nitride layer.

19. The method of claim 17, wherein the final passivation layer is a polyimide layer.
